(19) United States
(12) Patent Application Publication
(10) Pub. No.: US 2009/0178839 A1
(43) Pub. Date: Jul. 16, 2009

(54) RECOGNITION MARK AND METHOD FOR MANUFACTURING CIRCUIT BOARD

(76) Inventors: Toshiaki Takenaka, Kyoto (JP); Yukihiro Hiraishi, Hyogo (JP); Takao Okamoto, Kyoto (JP); Masaya Mada, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/297,076

(22) PCT Filed: Mar. 12, 2008
(86) PCT No.: PCT/JP2008/000537

§ 371 Date: Oct. 14, 2008

(30) Foreign Application Priority Data
Mar. 14, 2007 (JP) 2007 064751

(51) Int. Cl. H05K 1/11; B29C 39/00

(52) U.S. Cl. 174/266; 264/482; 264/406

(57) ABSTRACT

Through hole (3) for product, through holes (7a, 7b) for laminate recognition marks, through holes (8a, 8b) for an X-ray recognition marks are formed on prepreg sheet (1) having mold release films (2a, 2b) attached to the front and back surfaces thereof. By masking through holes (7a, 7b) for laminate recognition mark, conductive paste (4) is filled in through hole (3) for product and through holes (8a, 8b) for X-ray recognition marks. Thereafter, mold release films (2a, 2b) are removed so as to manufacture a circuit board. Since conductive paste (4) is not filled in through holes (7a, 7b) for laminate recognition marks, a recognition mark with high laminating accuracy can be easily obtained, and a high density and high quality circuit formation substrate having improved laminating accuracy can be obtained.

### TECHNICAL FIELD

The present invention relates to a recognition mark used in manufacturing a circuit board used for various electronic equipment and to a method for manufacturing a circuit board using the recognition mark.

### BACKGROUND ART

Recently, according to the trend toward small size and higher mounting density of electronic equipment, a circuit board on which electronic components are mounted is shifting from a conventional single-sided board to double-sided and multi-layer boards. Thus, a high-density board on which a larger number of circuits and components can be integrated has been developed.

In particular, in increasing the density of multi-layer board, circuit patterns have become finer, so that a larger number of layers of circuit patterns and thinner boards have been demanded.

In such a circuit board, it becomes necessary to newly develop a connecting method for carrying out an inner-via-hole connection between the circuit patterns in a plurality of layers together with a structure with high reliability.

Hereinafter, a conventional method for manufacturing a four-layer board by an inner-via-hole connection with the use of a conductive paste is described by taking a manufacturing method disclosed in patent document 1 as an example.

Firstly, a method for manufacturing a double-sided board as a core substrate of a multi-layer board connected by an inner via hole with the use of a conductive paste and a method for filling a conductive paste are described.

FIGS. 10A to 10H are sectional views each showing a step of a conventional method for manufacturing a double-sided board. A material of the board shown in FIG. 10A is a laminated prepreg including prepreg sheet 21 and mold release films 22a and 22b.

As prepreg sheet 21, a base material made of a composite material prepared, for example, by impregnating a thermo-setting epoxy resin into a wholly aromatic polyamide fiber non-woven fabric or a glass cloth is used. Plastic films having a mold release layer portion, for example, mold release films 22a and 22b made of, for example, polyethylene terephthalate are attached to the front and back surfaces of prepreg sheet 21.

As a method for attaching mold release films 22a and 22b to prepreg sheet 21, a method for continuously attaching mold release films 22a and 22b by melting a resin component of prepreg sheet 21 by using a laminating device has been proposed.

Next, as shown in FIG. 10B, through hole 23 is formed by, for example, a laser processing method. At this time, through holes 27a and 27b for recognition marks (hereinafter, referred to as “through holes 27A and 27b”) used in manufacture are formed by a laser processing method simultaneously with the formation of through hole 23 for product (hereinafter, referred to as “through hole 23”) used in an interlayer connection.

Next, as shown in FIG. 10C, conductive paste 24 filled into hole 23 and through holes 27a and 27b.

Conductive paste 24 is prepared by mixing and kneading metallic particles such as copper particles with thermosetting resin such as epoxy resin in order to provide conductivity. Filling can be carried out by using a well-known technique such as a printing method using squeegee 26.

Next, as shown in FIG. 10D, mold release films 22a and 22b are removed. Since mold release films 22a and 22b are attached to the surface of prepreg 21 with a slightly melted resin part, they can be removed easily.

FIG. 11 is a sectional view showing a through hole after the mold release films have been removed. After mold release films 22a and 22b are removed, as shown in FIG. 11, conductive paste 24 has a shape protruding by a portion corresponding to the thickness of mold release films 22a and 22b.

Then, as shown in FIG. 10E, metal foils 25a and 25b such as copper foils are disposed on the front and back surfaces of prepreg sheet 21, and then they are heated and pressurized by hot pressing so as to be molded and cured as shown in FIG. 10F. Thus, prepreg sheet 21 and metal foils 25a and 25b are attached to each other, and conductive paste 24 is compressed. Thereby, metal foils 25a and 25b disposed on the front and back surfaces are electrically connected to each other via conductive paste 24 filled in through holes 23 provided in predetermined positions.

Next, through holes 27a and 27b formed in prepreg sheet 21 are detected by using an X-ray via metal foils 25a and 25b, and as shown in FIG. 10G, through holes 29a and 29b for exposure (hereinafter, referred to as “through holes 29a and 29b”) are formed in the centers of through holes 27a and 27b by using, for example, a drill, respectively.

Then, through holes 29a and 29b and an exposure film are positioned with respect to each other (not shown), and predetermined etching resist patterns are formed by, for example, a photographic developing method. Thereafter, etching is carried out selectively by using a drug solution such as a copper (II) chloride solution. Thus, as shown in FIG. 10H, double-sided board 30 having circuit patterns 32a and 32b and recognition patterns 33a and 33b for laminating the following layer thereon can be obtained.

Next, a method for manufacturing a four-layer board is described.

Firstly, as shown in FIG. 12A, double-sided board 30 having inner layer conductive circuit patterns (circuit patterns formed on a circuit board as an inner layer) 32a and 32b produced as mentioned above and recognition patterns 33a and 33b for laminating the following layer, and two prepreg sheets 21a and 21b produced by the manufacturing method shown in FIGS. 10A to 10D are prepared. Two prepreg sheets 21a and 21b have through hole 23 and through holes 27a and 27b, which are filled with conductive paste 24 by a printing method. Through hole 23 is formed in a portion facing predetermined positions in circuit patterns 32a and 32b on double-sided board 30. Through holes 27a and 27b are formed in portions facing the positions of laminate recognition patterns 33a and 33b on double-sided board 30.

Next, as shown in FIG. 12B, firstly, through holes 27a and 27b in prepreg sheet 21b are detected by a camera, and then, image processing is carried out so as to obtain the center of gravity of a diameter of filled conductive paste 24. Based on the result, prepreg sheet 21b is moved in the X, Y, and θ directions so as to be positioned to a predetermined position and disposed on metal foil 25b. Thereafter, laminate recognition patterns 33a and 33b of double-sided board 30, which are formed on the portions facing the prepreg sheet 21b, are detected by a camera, and then image processing is carried out so as to obtain the center of gravity. Based on the result, double-sided board 30 is moved in the X, Y, and θ directions so as to be positioned with respect to through holes 27a and 27b in prepreg sheet 21b, and disposed on prepreg sheet 21b.

Furthermore, as shown in FIG. 12C, through holes 27a and 27b in prepreg sheet 21b, which are formed in a position facing recognition patterns 33a and 33b formed on double-sided board 30, are detected by a camera, and image processing is carried out so as to obtain the center of gravity of a diameter of filled conductive paste 24. Thereafter, prepreg sheet 21b is moved in the X, Y, and θ directions so as to be positioned with respect to recognition patterns 33a and 33b of double-sided board 30, and disposed on double-sided board 30.

The reason why through holes 27a and 27b and laminate recognition patterns 33a and 33b are detected by a camera such as CCD is that device cost is relatively cheap and a configuration of the device is simple and prevailing, and furthermore, the productivity is high.

Next, as shown in FIG. 12D, metal foils 25a and 25b are disposed on the surfaces of prepreg sheets 21a and 21b, respectively, and they are heated and pressurized by hot pressing so as to be molded and cured. Thus, prepreg sheets 21a and 21b and metal foils 25a and 25b are attached to each other. Thus, conductive paste 24 is compressed and metal foils 25a and 25b on the front and back surfaces are electrically connected to circuit patterns 32a and 32b on inner double-sided board 30 by conductive paste 24 filled in through holes 23 provided in predetermined positions.

Next, through holes 27a and 27b formed on prepreg sheets 21a and 21b are detected by an X-ray via metal foils 25a and 25b. Then, as shown in FIG. 12E, through holes 29a and 29b are formed in the centers of gravity of through holes 27a and 27b by using, for example, a drill.

Then, as shown in FIG. 12F, through holes 29a and 29b and an exposure film are positioned with respect to each other (not shown), and predetermined etching resist patterns are formed by, for example, a photographic developing method. Thereafter, selective etching is carried out by using a drug solution such as a copper (II) chloride solution, circuit patterns 32a and 32b on the outer layer are formed. Thus, four-layer board 40 is obtained.

However, in the above-mentioned method for manufacturing a circuit board, when a recognition mark is formed in a prepreg sheet having mold release films attached on the front and back surfaces thereof by a laser processing method, recognition error or displacement of the center of gravity may occur. Thus, it is not advantageous for a circuit board that requires positioning accuracy.

This is described with reference to FIG. 13 showing the correspondence between a sectional view and a plan view of prepreg sheet 21 after through holes are processed. Specifically, processing energy is different between a resin component, aramid fiber and glass cloth constituting the prepreg sheet and plastics such as polyethylene terephthalate as base materials of the mold release film. Therefore, for example, when an irradiated laser light is distorted, through hole 23 may be formed in a state in which mold release film 22a at the incident side (the front surface of prepreg sheet 21) is deformed with respect to the outgoing side (the back surface of prepreg sheet 21) of the laser light as shown in FIG. 13. That is to say, the diameter of the incident side of through hole 23a is larger than the diameter at the outgoing side of through hole 23.

When conductive paste 24 is filled in through hole 23 that has been deformed in this way, as shown in FIG. 14, center of gravity 37a of the diameter of conductive paste 24 at the incident side is displaced from center of gravity 37b of the diameter of conductive paste 24 at the outgoing side.

Thereafter, when recognition mark in prepreg sheet 21 is detected by a camera by using transmitted light and reflected light, the diameter at the incident side is selected. On the other hand, when through hole 23 for a recognition mark is detected by an X-ray via metal foils 25a and 25b after hot pressing, the diameter at the outgoing side whose concentration of conductive paste 24 is high is selected. Therefore, displacement of through holes 23 for a recognition mark occurs between both steps.

FIG. 15 is a plan view showing examples of other recognition marks in a conventional example. Recently, as shown in FIG. 15, recognition marks 27 including a plurality of through holes have been proposed so that even if a part of recognition marks 27 is lost and the center of gravity of recognition mark 27 becomes abnormal mark 38, the center of gravity can be obtained by the other recognition marks 27. However, when laser light is distorted when recognition mark 27 is processed in the above-mentioned prepreg sheet 21, diameters of conductive paste 24 are different between the incident side and outgoing side in the same direction and the center of gravity may be displaced as in the case where a single through hole is formed in the same direction.

Therefore, in order to release the displacement of the center of gravity of a recognition mark in such a manufacturing method, a recognition mark that is not affected by the difference in the diameter between the conductive paste at the incident side and that at the outgoing side where distorted laser light is generated, and a method for manufacturing a circuit board using the same are required.

[Patent document 1] Japanese Patent Application Unexamined Publication No. H6-268345

### SUMMARY OF THE INVENTION

A recognition mark of the present invention is provided in at least two or more places in a prepreg sheet, and includes a through hole filled with a conductive filler material, and a through hole that is not filled with a conductive filler material or a through hole with a conductive filler material left on the wall surface thereof.

Thus, displacement of the center of gravity of the recognition mark due to distortion of the laser light in manufacture is avoided, and an effect of obtaining a multi-layer circuit board with high laminating accuracy can be achieved.

Furthermore, a method for manufacturing a circuit board of the present invention includes: attaching a mold release film to front and back surfaces of a prepreg sheet; forming a through hole for an interlayer connection and a plurality of through holes for recognition marks; filling a conductive filler material into the through hole for an interlayer connection and a part of the plurality of through holes for recognition marks; and removing the mold release film from the prepreg sheet.

Thus, a recognition mark with high laminating accuracy can be obtained easily. As a result, an inner layer substrate and prepreg sheet match well each other. The conductive filler material can be electrically connected by interlayer connection means stably. Thus, high-quality and high-density circuit board can be provided.

### BRIEF DESCRIPTION OF THE DRAWINGS

FIG. 1A is a sectional view showing a step in a method for manufacturing a circuit board in accordance with an exemplary embodiment of the present invention.

FIG. 1B is a sectional view showing a step in the method for manufacturing a circuit board in accordance with the exemplary embodiment.

FIG. 1C is a sectional view showing a step in the method for manufacturing a circuit board in accordance with the exemplary embodiment.

FIG. 1D is a sectional view showing a step in the method for manufacturing a circuit board in accordance with the exemplary embodiment.

FIG. 1E is a sectional view showing a step in the method for manufacturing a circuit board in accordance with the exemplary embodiment.

FIG. 1F is a sectional view showing a step in the method for manufacturing a circuit board in accordance with the exemplary embodiment.

FIG. 1G is a sectional view showing a step in the method for manufacturing a circuit board in accordance with the exemplary embodiment.

FIG. 1H is a sectional view showing a step in the method for manufacturing a circuit board in accordance with the exemplary embodiment.

FIG. 2 is a plan view showing positions of recognition marks in accordance with the exemplary embodiment.

FIG. 3A is a plan view showing a processing method of a through hole for recognition in accordance with the exemplary embodiment.

FIG. 3B is a sectional view showing a processing method of a through hole for recognition in accordance with the exemplary embodiment.

FIG. 4 is a plan view showing a recognition mark in accordance with the exemplary embodiment.

FIG. 5 is a view showing a correspondence between a sectional view and a plan view after the through hole is processed in accordance with the exemplary embodiment.

FIG. 6A is a sectional view showing a through hole after a conductive paste is filled in accordance with the exemplary embodiment.

FIG. 6B is a sectional view showing a through hole that is not filled with a conductive paste in accordance with the exemplary embodiment.

FIG. 7 is a sectional view showing another through hole using a conductive paste in accordance with the exemplary embodiment.

FIG. 8A is a sectional view showing a step of a method for manufacturing a multi-layer circuit board in accordance with the exemplary embodiment.

FIG. 8B is a sectional view showing a step of a method for manufacturing a multi-layer circuit board in accordance with the exemplary embodiment.

FIG. 8C is a sectional view showing a step of a method for manufacturing a multi-layer circuit board in accordance with the exemplary embodiment.

FIG. 8D is a sectional view showing a step of a method for manufacturing a multi-layer circuit board in accordance with the exemplary embodiment.

FIG. 8E is a sectional view showing a step of a method for manufacturing a multi-layer circuit board in accordance with the exemplary embodiment.

FIG. 8F is a sectional view showing a step of a method for manufacturing a multi-layer circuit board in accordance with the exemplary embodiment.

FIG. 9A is a sectional view showing a center of gravity of a recognition mark before a conductive paste is filled, used in a method for manufacturing a multi-layer circuit board in accordance with the exemplary embodiment.

FIG. 9B is a sectional view showing a center of gravity of a recognition mark after a conductive paste is filled, used in a method for manufacturing a multi-layer circuit board in accordance with the exemplary embodiment.

FIG. 10A is a sectional view showing a step in a method for manufacturing a double-sided circuit board on both surfaces in a conventional example.

FIG. 10B is a sectional view showing a step in a method for manufacturing the double-sided circuit board.

FIG. 10C is a sectional view showing a step in a method for manufacturing the double-sided circuit board.

FIG. 10D is a sectional view showing a step in a method for manufacturing the double-sided circuit board.

FIG. 10E is a sectional view showing a step in a method for manufacturing the double-sided circuit board.

FIG. 10F is a sectional view showing a step in a method for manufacturing the double-sided circuit board.

FIG. 10G is a sectional view showing a step in a method for manufacturing the double-sided circuit board.

FIG. 10H is a sectional view showing a step in a method for manufacturing the double-sided circuit board.

FIG. 11 is a sectional view showing a through hole after a mold release film is removed in a conventional example.

FIG. 12A is a sectional view showing a step in a method for manufacturing a multi-layer circuit board in a conventional example.

FIG. 12B is a sectional view showing a step in the method for manufacturing the multi-layer circuit board.

FIG. 12C is a sectional view showing a step in the method for manufacturing the multi-layer circuit board.

FIG. 12D is a sectional view showing a step in the method for manufacturing the multi-layer circuit board.

FIG. 12E is a sectional view showing a step in the method for manufacturing the multi-layer circuit board.

FIG. 12F is a sectional view showing a step in the method for manufacturing the multi-layer circuit board.

FIG. 13 is a view showing a correspondence between a sectional view and a plan view after a through hole is processed in a conventional example.

FIG. 14 is a sectional view showing a recognition mark in a conventional example.

FIG. 15 is a sectional view showing another recognition mark in a conventional example.

### REFERENCE MARKS IN THE DRAWINGS

1, 1a, 1b prepreg sheet
2a, 2b mold release film
3, 3a through hole
4 conductive paste
5a, 5b metal foil
6 squeegee
7, 7a, 7b through hole for laminate recognition mark
8a, 8b through hole for an X-ray recognition mark
9a, 9b through hole for exposure
10 double-sided board
11 mask
12a, 12b circuit pattern
13a, 13b laminate recognition pattern
14a, 14b X-ray recognition pattern
15 filling area of conductive paste
16 laser light
17, 17a, 17b center of gravity
18 altered layer
20 four-layer board

### DETAILED DESCRIPTION OF THE PREFERRED EMBODIMENTS

A recognition mark of the present invention is provided in at least two or more places in a prepreg sheet, and includes a through hole filled with a conductive filler material, and a through hole that is not filled with a conductive filler material or a through hole with a conductive filler material left on the wall surface thereof. Thus, displacement of the center of gravity of the recognition mark due to distortion of the laser light in manufacture is avoided, and an effect of obtaining a multi-layer circuit board with high laminating accuracy can be achieved.

Furthermore, the through hole that is not filled with a conductive filler material or the through hole with a conductive filler material left on the wall surface thereof is formed at the outer side with respect to the through hole filled with a conductive filler material, for example, on the edge side of the prepreg sheet. This makes it easy to mask the through holes that are not filled with a conductive filler material when a conductive filler material is filled in the through hole for an interlayer connection. This also makes it possible to form the through hole with a conductive filler material left on the wall surface thereof without affecting the quality of the through hole for an interlayer connection. In addition, this makes it easy to detect the through hole that is not filled with a conductive filler material or the through hole with a conductive filler material left on the wall surface thereof with transmitted light and reflected light by using a camera. Therefore, displacement of the center of gravity of a recognition mark due to distortion of the laser light in manufacture is avoided. Consequently, a multi-layer circuit board with high laminating accuracy can be obtained.

Furthermore, an altered layer is formed on a processed wall of the through hole. Thus, the contour of the through hole is made to be distinct and can be easily detected.

Furthermore, the hole diameter of the through hole that is not filled with a conductive filler material or the through hole with a conductive filler material left on the wall surface thereof is larger than the diameter of the through hole filled with a conductive filler material. Thus, it is possible to prevent the center of gravity of the through hole from being displaced due to powder generated in processing or dust clogging in the through holes.

Furthermore, at least one from the through hole that is not filled with a conductive filler material, the through hole with a conductive filler material left on the wall surface thereof, and the through hole filled with a conductive filler material is formed of a plurality of through holes. Thus, even if the processing position accuracy of the through hole is deteriorated, it is possible to obtain the center of gravity from the plurality of through holes, and to enhance the laminating accuracy.

The through hole with a conductive filler material left on the wall surface thereof is formed by laser processing, and the altered layer is formed of a carbonized resin part in the prepreg sheet. Thus, the altered layer can be formed efficiently.

Furthermore, the through hole that is not filled with a conductive filler material or the through hole with a conductive filler material left on the wall surface thereof is formed by carrying out irradiation with laser light several times. Thus, it can be formed efficiently without deteriorating the productivity.

Furthermore, a method for manufacturing a circuit board of the present invention includes: attaching a mold release film to front and back surfaces of a prepreg sheet; forming a through hole for an interlayer connection and a plurality of through holes for recognition marks; filling a conductive filler material into the through hole for an interlayer connection and a part of the plurality of through holes for recognition marks; and removing the mold release film from the prepreg sheet.

Thus, a recognition mark with high laminating accuracy can be obtained easily. As a result, an inner layer substrate and prepreg sheet match well each other. The conductive filler material can be electrically connected by interlayer connection means stably. Thus, high-quality and high-density circuit board can be provided.

Furthermore, a method for manufacturing a circuit board of the present invention includes: attaching a mold release film to front and back surfaces of a prepreg sheet; forming a through hole for an interlayer connection and a plurality of through holes for recognition marks; filling a conductive filler material into the through hole for an interlayer connection and the plurality of through holes for recognition marks; and removing the mold release film from the prepreg sheet. The filling of the conductive filler material into the plurality of through holes for recognition marks includes a step of allowing the conductive filler material to drop off from a part of the through holes and allowing the conductive filler material to be left only on the wall surface of the through hole.

Thus, a recognition mark with high laminating accuracy can be obtained easily. In addition, since it is not necessary to mask in part when the conductive filler material is filled, the productivity can be improved and the ratio of the effective area of the substrate material such as a prepreg sheet can be increased.

Furthermore, the hole diameter of the part of the through holes from which the conductive filler material drops off is larger than the hole diameter of the other through holes. Thus, the filled conductive filler material drops off from the through hole and the conductive filler material can be left only on the wall surface of the through hole, thus enabling the contour of the through hole to be made distinct.

Furthermore, a method for manufacturing a circuit board of the present invention includes: preparing a prepreg sheet including the through hole for an interlayer connection filled with the conductive filler material produced in the removing of the mold release film from the prepreg sheet mentioned above, and a recognition mark including the through hole filled with a conductive filler material, and the through hole that is not filled with a conductive filler material or the through hole with the conductive filler material left on the wall surface thereof; preparing an inner layer substrate provided with a circuit pattern and a laminate recognition pattern and a metal foil; detecting the through hole filled with the conductive filler material, and the through hole that is not filled with a conductive filler material or the through hole with the conductive filler material left on the wall surface of the through hole in the recognition marks in the prepreg sheet and a laminate recognition pattern on the inner layer substrate, positioning them each other, and disposing the prepreg sheet on the inner layer substrate; substantially positioning and disposing the metal foil on the prepreg sheet and then pressing and pressurizing by hot pressing; and forming a through hole for exposure by detecting the through hole filled with the conductive filler material in the recognition marks.

Furthermore, the detection and positioning of the recognition mark in the prepreg sheet and the laminate recognition pattern in the inner layer substrate are carried out through detection by a camera and image processing.

Thus, even when the recognition mark of the prepreg sheet is processed in a distorted state, an image of transmitted light becomes a minimum diameter portion of the through hole and is not affected by the distortion of the laser light. As a result, accurate detection of the through hole for a recognition mark in the prepreg sheet and laminate recognition patterns on the inner layer substrate can be carried out easily by a transmitted light. In addition, image processing and a positioning operation are carried out at high speed, so that the productivity is high.

Furthermore, the forming of the through hole for exposure by detecting the through hole filled with a conductive filler material in the recognition marks is carried out by detecting the through hole with an X-ray and by drill processing with respect to the center of the gravity of the through hole.

Thus, it is possible to detect the center of gravity without being affected by the conductive filler material filled in the incident side where a recognition mark in the prepreg sheet is processed in a distorted shape and to form a through hole for exposure with high position accuracy.

As mentioned above, specifically, according to the present invention, a recognition mark used when an inner layer substrate is positioned and laminated with respect to the inner layer circuit board and the prepreg sheet, and a recognition mark detected by an X-ray via a metal foil after hot pressing are provided. The recognition mark at the time of lamination, which is provided in the prepreg sheet, is formed by the through hole that is not filled with the conductive filler material or the through hole with the conductive filler material formed on the inner wall. The recognition mark detected by an X-ray is formed by the through hole filled with the conductive filler material.

Therefore, according to the present invention, it is possible to improve the positioning accuracy of inner layer circuit board and the prepreg sheets to be positioned and laminated on the front and back surfaces of the circuit board, and to facilitate a method for manufacturing a highly accurate circuit board.

Hereinafter, a recognition mark and a method for manufacturing a circuit board in accordance with an exemplary embodiment of the present invention are described with reference to the drawings.

### EXEMPLARY EMBODIMENT

In this exemplary embodiment, as a conductive filler material, a conductive paste is used. Firstly, a method for manufacturing a double-sided circuit board as an inner layer substrate in a multi-layer circuit board with an inner-via-hole connection by a conductive paste is described.

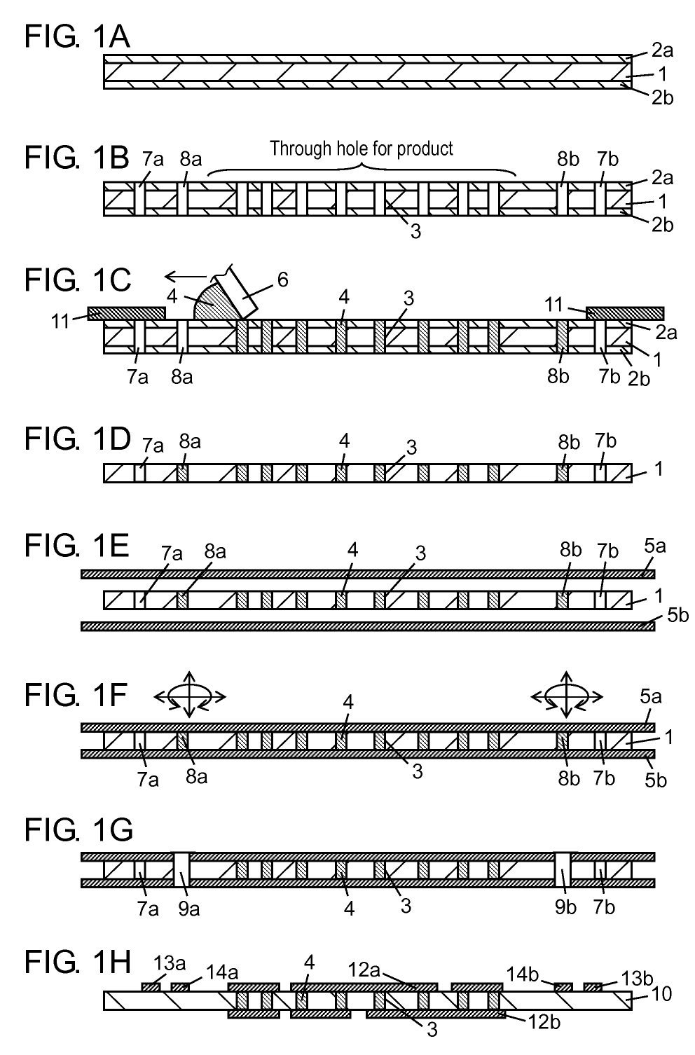

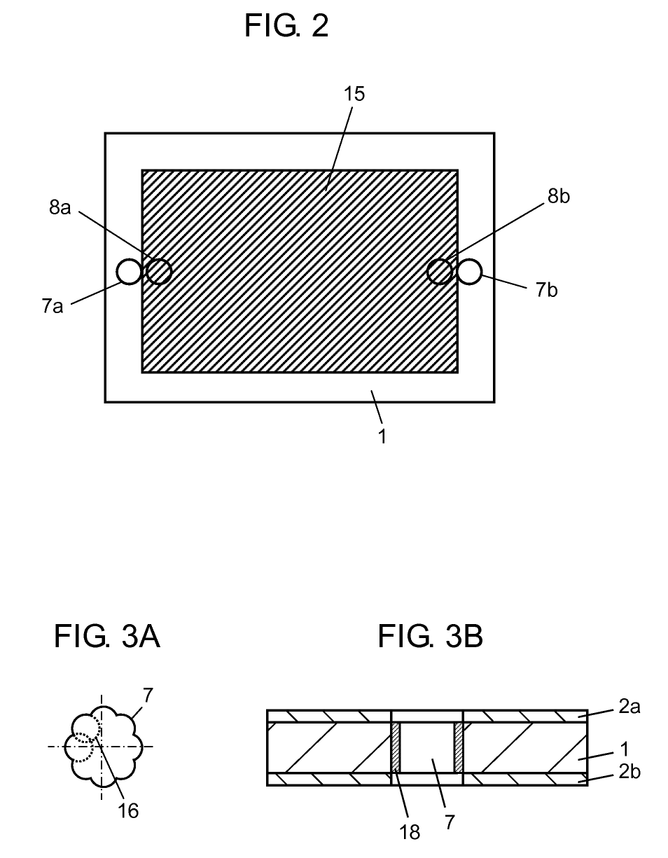

FIGS. 1A to 1H are sectional views each showing a step of a method for manufacturing a circuit board in accordance with an exemplary embodiment of the present invention. FIGS. 1A to 1H are a process sectional view of a method for manufacturing a circuit board in the present invention.

Firstly, as shown in FIG. 1A, mold release films 2a and 2b are attached to the front and back surfaces of prepreg sheet 1 by using a laminating device.

As prepreg sheet 1, a base material made of a composite material prepared, for example, by impregnating a thermo-setting epoxy resin into a wholly aromatic polyamide fiber non-woven fabric or a glass cloth is used. Plastic films having a mold release layer portion, for example, mold release films 2a and 2b made of, for example, polyethylene terephthalate are attached to the front and back surfaces of prepreg sheet 1 by using a laminating device.

Next, as shown in FIG. 1B, through hole 3 as an inner via hole is formed by a laser processing method. At this time, through holes 7a and 7b for laminate recognition marks (hereinafter, referred to as “through holes 7A and 7b”), which are not filled with the following conductive paste 4, and through holes 8a and 8b for X-ray recognition marks (hereinafter, referred to as “through holes 8A and 8b”), which are used for position recognition after hot pressing and which are filled with conductive paste 4, are formed by a laser processing method simultaneously with the formation of through hole 3 for product, that is, for an interlayer connection.

FIG. 2 is a plan view showing a position of a recognition mark in accordance with this exemplary embodiment. In this exemplary embodiment, as shown in FIG. 2, through holes 8a and 8b having a hole diameter of about 150 μm are formed in filling area 15 of the following conductive paste 4, and through holes 7a and 7b having a hole diameter of about 300 μm are formed outside filling area 15 of conductive paste 4, that is, the edge side of prepreg sheet 1 that is an outer side seen from the center.

FIGS. 3A and 3B are a plan view and a sectional view showing a processing method of a through hole for recognition in this exemplary embodiment, respectively. In this exemplary embodiment, through holes 7a and 7b are formed so that they have a hole diameter of about 300 μm by carrying out irradiation with laser light 16 several times at the time of laser processing and by carrying out processing in a state in which diameters of laser light 16 are overlapped in order to prevent the generation of powder or clogging of dust. On the processed walls of through holes 7a and 7b, as shown in FIG. 3B, altered layer 18 is formed of a resin part in prepreg sheet 1 that is carbonized by heat of laser light 16. Herein, the diameters of through holes 7a and 7b are made to be 300 μm by carrying out irradiation with laser light several times. However, the diameter may be the same as that of through hole 3 for product (hereinafter, referred to as “through hole 3”) or the diameter of through holes 8a and 8b.

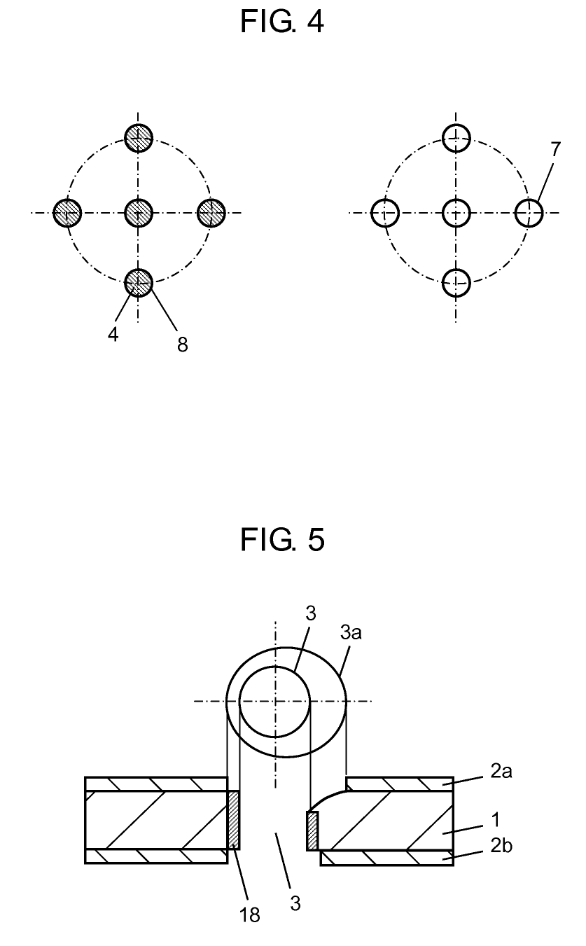

FIG. 4 is a plan view showing a recognition mark in this exemplary embodiment. In this exemplary embodiment, the number of through holes 7a and 7b and through holes 8a and 8b are respectively one. However, as shown in FIG. 4, the recognition mark may be formed of a plurality of through holes 7 and 8. The number of through holes 7 and 8 may be set arbitrarily.

Furthermore, when prepreg sheet 1 of four layers is formed, through holes 7a and 7b and through holes 8a and 8b are essential. However, when a double-sided board is formed, since metal foils 5a and 5b are positioned and disposed on the front and back surfaces of prepreg sheet 1, only through holes 8a and 8b may be formed.

FIG. 5 is a view showing a correspondence between a sectional view and a plan view after a through hole is processed in this exemplary embodiment. When laser light is distorted at the time of laser processing, as shown in FIG. 5, since energy of the laser light in the distorted portion is small, through hole 3a is formed in the upper mold release film 2a that is the incident side of the laser light on prepreg sheet 1. However, through hole 3a does not penetrate prepreg sheet 1 and a part thereof is processed. Therefore, through hole 3a of upper mold release film 2a has a larger diameter than the hole diameter of prepreg sheet 1 and is formed in a distorted state. On the other hand, the lower mold release film 2b that is the outgoing side of the laser light on prepreg sheet 1 transmits only a part with large energy and provided with through hole 3. Therefore, through hole 3 is processed without being distorted.

Next, as shown in FIG. 1C, conductive paste 4 is filled into through hole 3 and through holes 8a and 8b that are the part of through holes constituting recognition marks by a well-known printing method. In a state in which through holes 7a and 7b are covered with mask 11, conductive paste 4 is filled by using squeegee 6. Thereby, conductive paste 4 can be prevented from entering through holes 7a and 7b. Therefore, conductive paste 4 is not filled in through holes 7a and 7b and conductive paste 4 can be filled in through holes 8a and 8b that are not covered with a plate frame.

Conductive paste 4 filled in through hole 3 is electrically connected to metal foils 5a and 5b such as copper foils to be attached to the front and back surfaces of prepreg sheet 1. Conductive paste 4 is formed by mixing and kneading metallic particles such as copper particles with thermosetting resin such as epoxy resin in order to provide conductivity.

Next, as shown in FIG. 1D, mold release films 2a and 2b are removed. After mold release films 2a and 2b are removed, conductive paste 4 has a shape protruding by a part corresponding to the thickness of mold release films 2a and 2b.

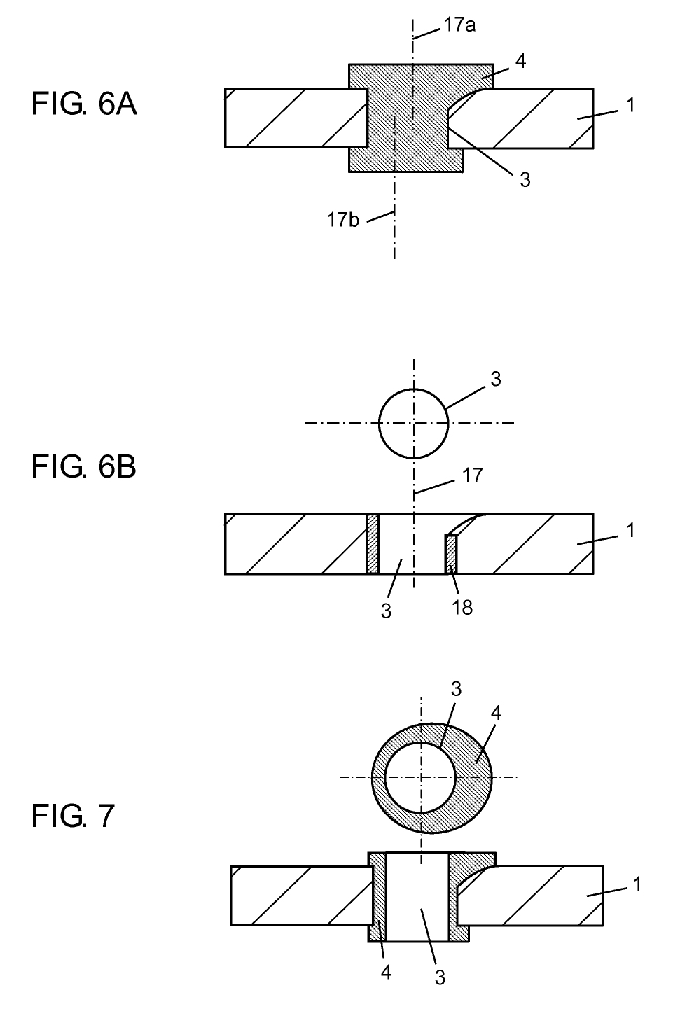

FIG. 6A is a sectional view showing a through hole filled with a conductive paste in accordance with this exemplary embodiment, and FIG. 6B is a sectional view showing a through hole that is not filled with the conductive paste. The processed surface of upper mold release film 2a is processed in a state in which the hole diameter is largely distorted in laser processing. Therefore, through hole 3 and through holes 8a and 8b, which are filled with conductive paste 4 after laser light processing is carried out, is a state as shown in FIG. 6A. That is to say, the diameter of conductive paste 4 that appears on the surface of prepreg sheet 1 at the side of the incident laser light becomes large by energy of the distorted laser light portion. On the other hand, the diameter of conductive paste 4 is small at the side of lower mold release film 2b, that is, at the outgoing side where the effect of the distortion of laser light is small. Therefore, center of gravity 17a of conductive paste 4 on the front surface and center of gravity 17b of conductive paste 4 on the back surface are displaced from each other.

On the other hand, in through holes 7a and 7b that are not filled with conductive paste 4, as shown in FIG. 6B, slight trace of melting is observed on the upper side of prepreg sheet 1 that is the incident side of the laser light. However, when seen by transmitted light, the effect of the melted trace portion of not-penetrating prepreg sheet 1 is not shown. Both through holes have a shape (circular shape) having center 17.

FIG. 7 is a sectional view showing another through hole using a conductive paste in this exemplary embodiment. In this exemplary embodiment, as through holes 7a and 7b, a through hole as it is formed by laser processing is used. However, as shown in FIG. 7, conductive paste 4 is left in the periphery of through holes 7a and 7b and on the wall surface of the through hole when conductive paste 4 is filled, thereby making the contour of the through hole distinct. Furthermore, also in the case where altered layer 18 is formed by laser processing, the contour of the through hole is made to be distinct.

In order to allow conductive paste 4 to be left only in a part shown in FIG. 7, through holes 7a and 7b having a hole diameter so that conductive paste 4 easily drops off are provided in the filling area. Thus, even when conductive paste 4 is filled in through holes 7a and 7b at the same time conductive paste 4 is filled in other through hole 3 or through holes 8a and 8b, conductive paste 4 in through holes 7a and 7b drops off. As a result, through holes 7a and 7b shown in FIG. 7 can be obtained. When the diameter of the through hole is larger than 1.5 times of the thickness of prepreg sheet 1, conductive paste 4 easily drops off. The larger the diameter is, the more easily conductive paste 4 drops off. Therefore, the diameter of the through hole may be set according to conductive paste 4 to be used and the filling method, and the like. When a conductive paste is filled in through holes 7a and 7b and then allowed to stand for a predetermined time, the conductive paste can be left only on the wall surface of the through hole.

Next, as shown in FIG. 1E, by using through holes 7a and 7b in prepreg sheet 1, metal foils 5a and 5b such as copper foils are disposed on the front and back surfaces. When a double-sided circuit board as an inner layer substrate is produced, since it may be substantially positioned with respect to metal foils 5a and 5b, positioning accuracy to be required is low. Therefore, through holes 8a and 8b filled with conductive paste 4 may be used.

Next, as shown in FIG. 1F, prepreg sheet 1 and metal foils 5a and 5b are attached to each other by heating and pressuring by hot pressing so as to be molded and cured while conductive paste 4 is compressed. Thus, metal foils 5a and 5b formed on the front and back surfaces are electrically connected to conductive paste 4 filled in through hole 3 provided in a predetermined position.

Next, through holes 8a and 8b formed in prepreg sheet 1 are detected via metal foils 5a and 5b by using an X-ray detector. Thereafter, as shown in FIG. 1G, through holes 9a and 9b for exposure (hereinafter, referred to as “through holes 9A and 9b”) are formed in the centers of gravity of through holes 8a and 8b by using a drill. In the centers of gravity of through holes 8a and 8b, a diameter of conductive paste 4 is large at the incident side processed in a distorted shape due to the effect of distortion of the laser light of prepreg sheet 1. However, the thickness of conductive paste 4 is as small as the thickness of mold release film 2a and the concentration is reduced. Therefore, the center of gravity of the diameter of conductive paste 4 at the laser outgoing side, which has a high concentration of conductive paste 4 and a small diameter of conductive paste 4, is selected.

Then, as shown in FIG. 1H, through holes 9a and 9b and an exposure film are positioned with respect to each other (not shown), and predetermined etching resist patterns are formed by, for example, a photographic developing method. Thereafter, selective etching is carried out by using a drug solution such as a copper (II) chloride solution, and thereby circuit patterns 12a and 12b, laminate recognition patterns 13a and 13b for four layers, and X-ray recognition patterns 14a and 14b are formed. Thus, double-sided circuit board 10 to be used as an inner layer substrate can be obtained. Herein, laminate recognition patterns 13a and 13b and X-ray recognition patterns 14a and 14b are formed only on the front surface of the double-sided circuit board. However, they may be provided on the back surface side according to detection means.

At least one from the through hole that is not filled with the conductive filler material, the through hole with the conductive filler material left on a wall surface of the through hole, and the through hole filled with a conductive filler material may be formed of a plurality of through holes.

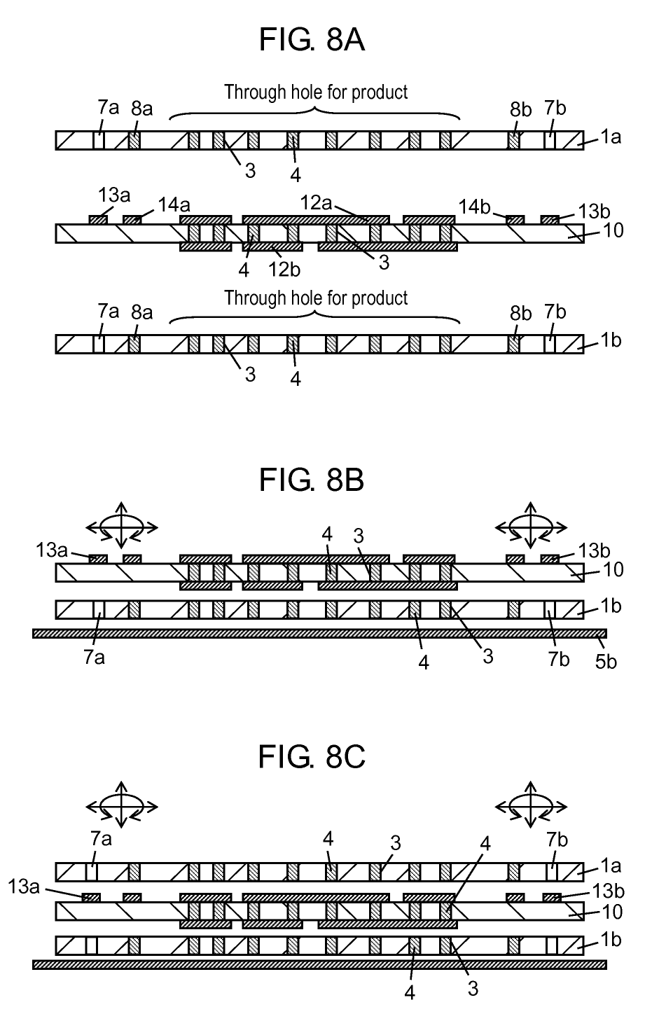

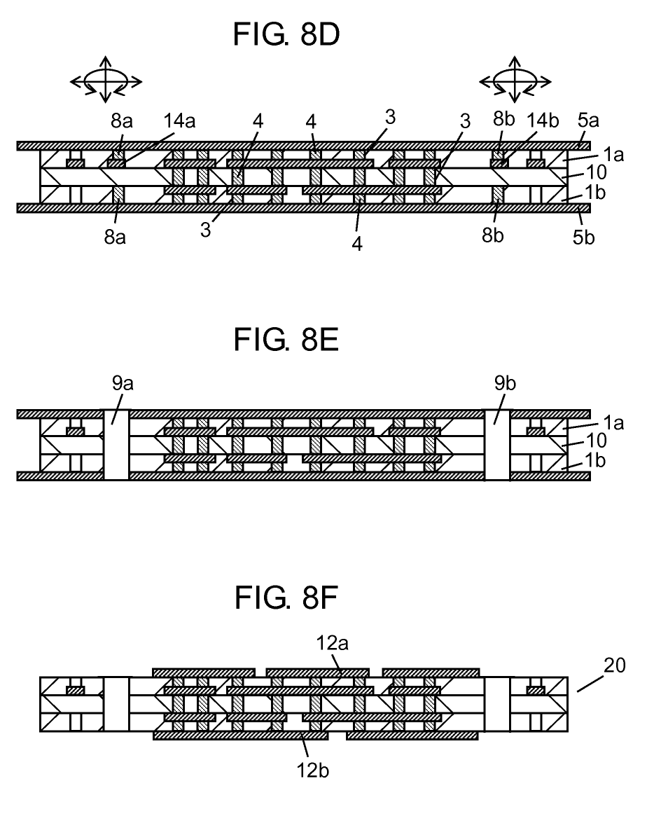

Next, a method for manufacturing a four-layer board is described. FIGS. 8A to 8F are a process sectional view showing steps of a method for manufacturing a four-layer board in the present invention.

Firstly, as shown in FIG. 8A, double-sided circuit board 10 produced as mentioned above and including inner layer conductive circuits 12a and 12b and recognition patterns 13a and 13b to be used for laminating the following layer, and two prepreg sheets 1a and 1b produced by the manufacturing method shown in FIGS. 1A to 1D are prepared. Through holes 3 filled with conductive paste 4 are formed in two prepreg sheets 1a and 1b facing the predetermined positions of circuit patterns 12a and 12b on double-sided circuit board 10. In addition, through holes 8a and 8b filled with conducive paste 4 are formed in the portions facing the positions of X-ray recognition patterns 14a and 14b. Furthermore, through holes 7a and 7b that are not filled with conducive paste 4 are formed in the portions facing the positions of laminate recognition patterns 13a and 13b.

Next, as shown in FIG. 8B, through holes 7a and 7b that are not filled with conductive paste 4 in prepreg sheet 1b are detected by a camera by using a transmitted light, and image processing is carried out so as to obtain the center of gravity. Then, prepreg sheet 1b is moved in the X, Y and θ directions and positioned with respect to a predetermined position. Thus, it is disposed on a metal foil 5b. Thereafter, laminate recognition patterns 13a and 13b on the upper surface of double-sided circuit board 10 formed in a portion facing prepreg sheet 1b are detected by a camera from the upper side, and image processing is carried out so as to obtain the center of gravity. Double-sided circuit board 10 is moved in the direction of X, Y and θ directions, positioned with respect to through holes 7a and 7b in prepreg sheet 1b, and disposed on prepreg sheet 1b.

Furthermore, an altered layer is formed on the processed walls of through holes 7a and 7b that are not filled with conductive paste 4. Thus, the contour of the through hole is made to be distinct, so that a through hole for laminate recognition mark can be detected stably. No recognition error is observed in 1000 pieces of samples.

In this exemplary embodiment, laminate recognition patterns 13a and 13b on the upper surface of double-sided circuit board 10 are detected by a camera from the upper side. However, laminate recognition patterns 13a and 13b on the lower surface of double-sided circuit board 10 may be detected by a camera from the lower side.

Furthermore, as shown in FIG. 8C, the centers of gravity of through holes 7a and 7b in prepreg sheet 1a are obtained. Through holes 7a and 7b are formed in a portion facing laminate recognition patterns 13a and 13b formed on double-sided circuit board 10 and are not filled with conductive paste 4. Thereafter, prepreg sheet 1b is moved in the X, Y and θ directions, positioned with respect to laminate recognition patterns 13a and 13b on double-sided circuit board 10, and disposed on double-sided circuit board 10.

Next, as shown in FIG. 8D, metal foil 5a is disposed on prepreg sheet 1a, and heated and pressurized by hot pressing so as to be molded and cured. Thus, prepreg sheet 1a and metal foils 5a and 5b are attached to each other, and conductive paste 4 is compressed. Thus, metal foils 5a and 5b on the front and back surfaces are electrically connected to circuit patterns 12a and 12b of double-sided circuit board 10 by conductive paste 4 filled in through hole 3 provided in a predetermined position.

Next, through holes 8a and 8b formed in prepreg sheets 1a and 1b are detected by an X-ray via metal foils 5a and 5b. Then, as shown in FIG. 8E, through holes 9a and 9b are formed in the centers of gravity of through holes 8a and 8b by using a drill.

Then, as shown in FIG. 8F, through holes 9a and 9b and an exposure film are positioned with respect to each other (not shown), and predetermined etching resist patterns are formed by, for example, a photographic developing method. Thereafter, selective etching is carried out by using a drug solution such as a copper (II) chloride solution, and thereby circuit patterns 12a and 12b are formed. Thus, four-layer board 20 is obtained.

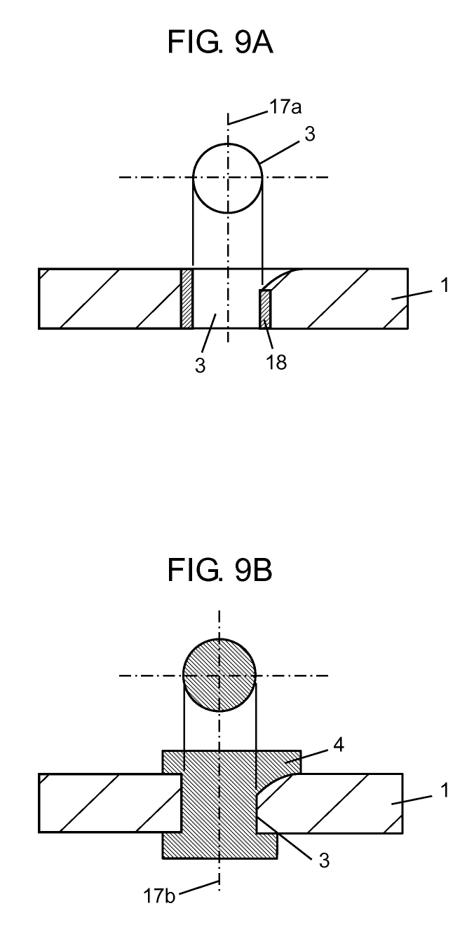

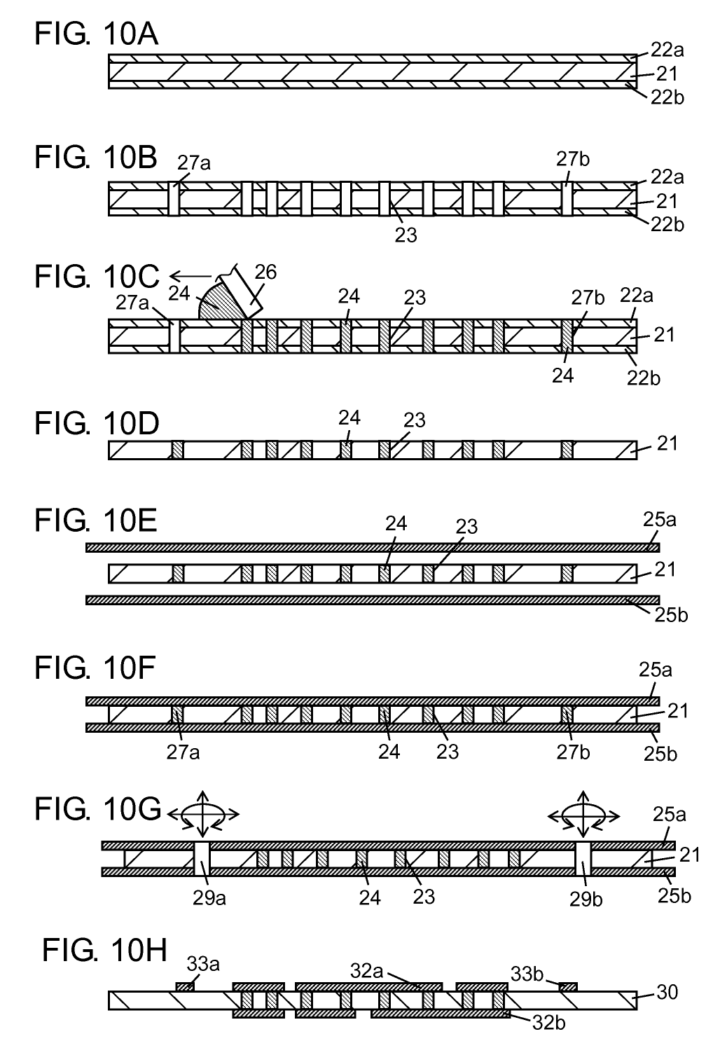

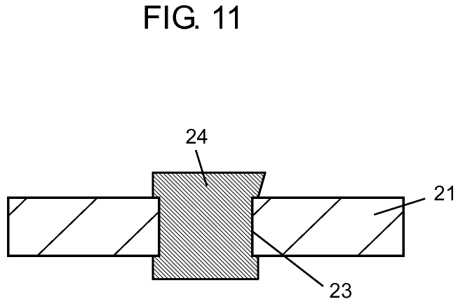

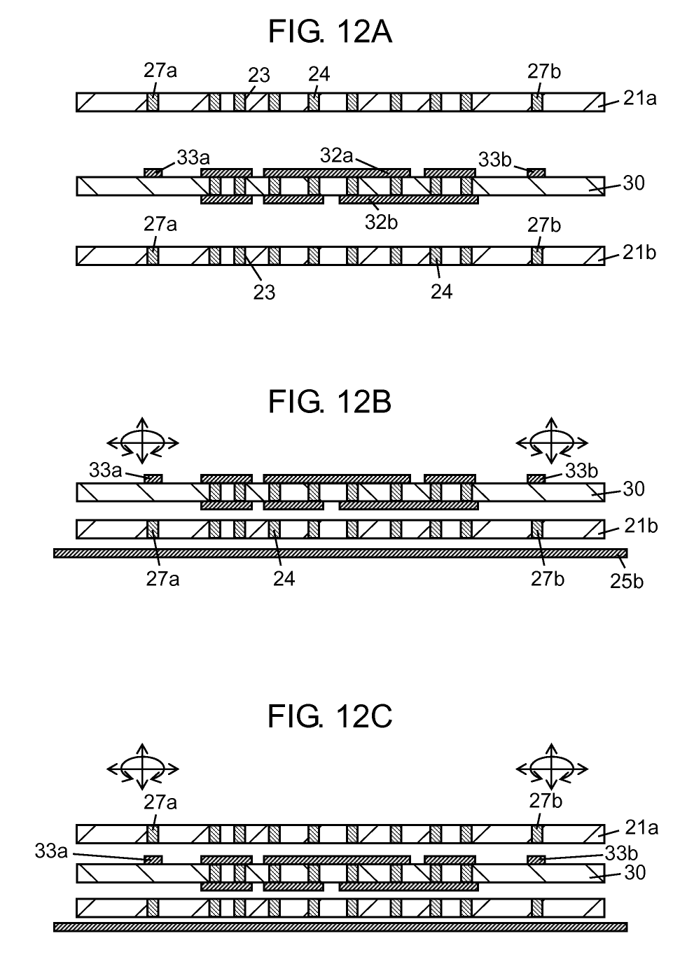

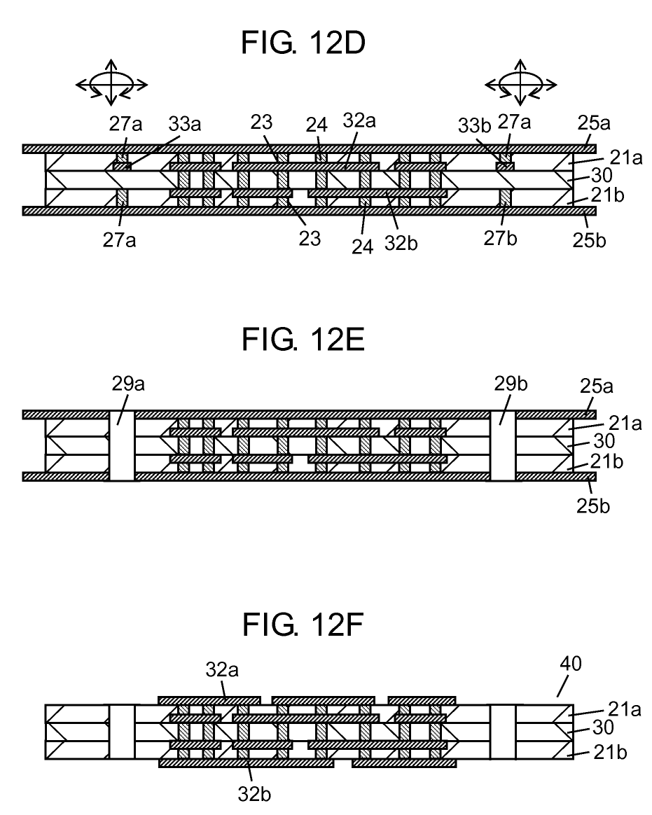

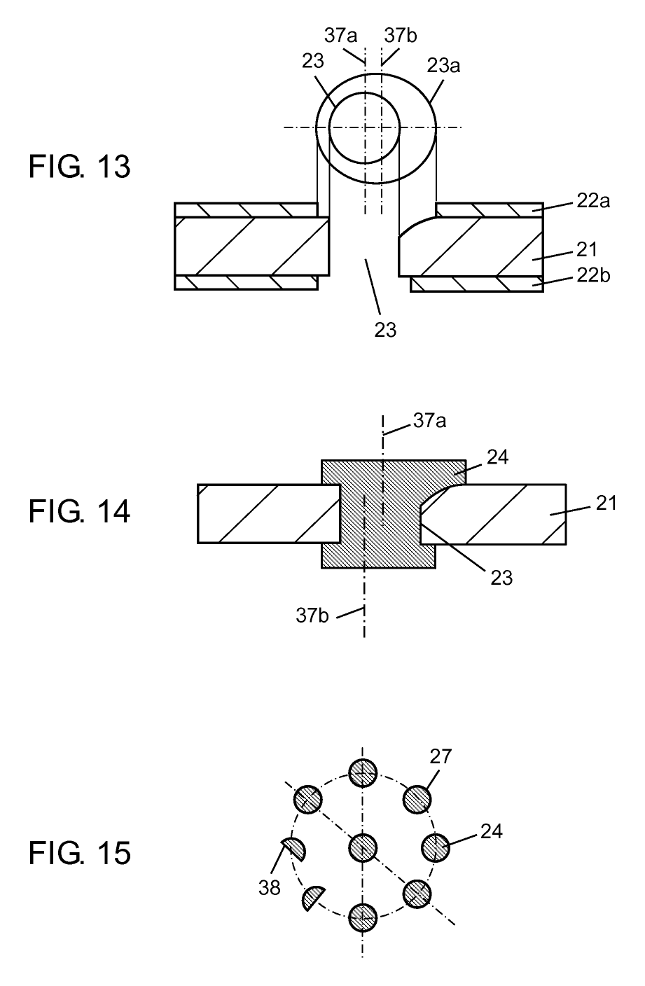

FIGS. 9A and 9B are sectional views showing the center of gravity of the recognition mark before and after a conductive paste to be used in the method for manufacturing a multi-layer circuit board is filled in this exemplary embodiment. As shown in FIG. 9A, the laminate recognition mark is formed by through holes 7a and 7b that are not filled with conductive paste 4. Therefore, even when the recognition mark of the prepreg sheet is processed in a state in which the laser light is distorted, an image of transmitted light becomes a minimum diameter portion of the through hole and is not affected by the distortion of the laser light. Therefore, it is possible to avoid the distortion of the center of gravity at the incident side and outgoing side, which is a problem in a conventional example when a recognition mark is formed by filling conductive paste 4.

Furthermore, by forming through holes 8a and 8b used after hot pressing in the vicinity of the laminate recognition mark, it is possible to prevent the deterioration of the position accuracy with respect to the laminate recognition mark. In addition, as shown in FIGS. 9A and 9B, centers of gravity 17a of through holes 7a and 7b and centers of gravity 17b of through holes 8a and 8b detected by an X-ray are obtained in the same positions in the through hole. Thus, the displacement of the center of gravity between at the time of laminating and at the time of detection with an X-ray can be prevented.

Furthermore, since through holes 7a and 7b are not filled with conductive paste 4, when the diameter of the through hole is smaller, dust or resin powder of the prepreg sheet accumulate easily. Therefore, when detection is carried out with a transmitted light by using a camera, the hole diameter becomes small and the positions of the centers of gravity may be displaced, so that position accuracy may be deteriorated. Therefore, it is desirable that the diameters of through holes 3a and 3b for laminate recognition marks have such a hole diameter that dust or resin powder of the prepreg sheet drops off.

Therefore, in this exemplary embodiment, the diameter of the through hole is made to be about 300 μm with respect to the thickness of the prepreg sheet of 100 μm. However, the diameter of through hole may be set according to the property of the prepreg sheet or the laser processing method. Furthermore, the through hole for laminate recognition mark is irradiated with laser light several times at the time of laser processing, and the diameters of the laser light are overlapped on each other so as to process one through hole, and a resin part in the prepreg sheet is carbonated by processing heat of laser so as to form a discoloration layer. Thereby, the contour of the laminate recognition mark can be detected easily.

In this exemplary embodiment, a method for manufacturing a four-layer board is described. However, completed substrate 20 is used as an inner layer substrate, and prepreg sheets 1a and 1b and metal foils 5a and 5b are positioned and disposed on the front and back surfaces of the inner layer substrate. The hot pressing and the formation of circuit are repeated, and thereby, an arbitrary multi-layer circuit board can be obtained.

In this exemplary embodiment, a configuration in which prepreg sheets 1a and 1b and metal foils 5a and 5b are disposed on the front and back surfaces of circuit board 10 is described. However, the same effect of the present invention can be obtained by a configuration in which circuit board 10 is disposed on the front and back surfaces of prepreg sheets 1a and 1b.

Furthermore, a configuration in which a conductive paste is used as interlayer connection means is described. As the conductive paste, besides a material formed by mixing and kneading conductive particles such as copper powder with thermosetting resin including a curing agent, various compositions, for example, a material formed by mixing and kneading conductive particles with appropriate polymer materials that may be discharged into the substrate material at the time of hot pressing or a solvent, and the like, can be used.

### INDUSTRIAL APPLICABILITY

As mentioned above, the present invention is useful for a method for manufacturing a circuit board and the like since an inner layer substrate and a prepreg sheet match well each other and an electric connection of a conductive paste by interlayer connection means can be carried out stably and with high quality.

1. A recognition mark provided in at least two or more places in a prepreg sheet, comprising:
a through hole filled with a conductive filler material; and
any of a through hole that is not filled with the conductive filler material and a through hole with the conductive filler material left on a wall surface of the through hole,
wherein the through hole is formed by irradiating the prepreg sheet with laser light from an incident side to an outgoing side.

2. The recognition mark of claim 1, wherein any of the through hole that is not filled with the conductive filler material and the through hole with the conductive filler material left on a wall surface of the through hole is provided on an outer side seen from a center with respect to the through hole filled with the conductive filler material.

3. The recognition mark of claim 1, wherein an altered layer is formed on a processed wall of the through hole.

4. The recognition mark of claim 1, wherein a hole diameter of any of the through hole that is not filled with the conductive filler material and the through hole with the conductive filler material left on a wall surface of the through hole is larger than a hole diameter of the through hole filled with the conductive filler material.

5. The recognition mark of claim 1, wherein at least one from the through hole that is not filled with the conductive filler material, the through hole with the conductive filler material left on a wall surface of the through hole, and the through hole filled with the conductive filler material is formed of a plurality of through holes.

6. The recognition mark of claim 3, wherein the altered layer is formed by a resin part in the prepreg sheet carbonized by processing heat of laser.

7. The recognition mark of claim 4, wherein any of the through hole that is not filled with the conductive filler material and the through hole with the conductive filler material left on a wall surface of the through hole is formed by carrying out irradiation with laser light a plurality of times.

8. A method for manufacturing a circuit board, the method comprising:
attaching a mold release film to front and back surfaces of a prepreg sheet;
forming a through hole for an interlayer connection and a plurality of through holes for recognition marks in the prepreg sheet having the mold release film attached to the front and back surfaces thereof;
filling a conductive filler material into the through hole for an interlayer connection and a part of the plurality of through holes for recognition marks; and
removing the mold release film from the prepreg sheet,
wherein the through hole is formed by irradiating the prepreg sheet with laser light from an incident side to an outgoing side.

9. A method for manufacturing a circuit board, the method comprising:
attaching a mold release film to front and back surfaces of a prepreg sheet;
forming a through hole for an interlayer connection and a plurality of through holes for recognition marks in the prepreg sheet having the mold release film attached to the front and back surfaces thereof;
filling a conductive filler material into the through hole for an interlayer connection and the plurality of through holes for recognition marks; and
removing the mold release film from the prepreg sheet,
wherein the filling of a conductive filler material into the plurality of through holes for recognition marks includes allowing the conductive filler material to drop off from a part of the through holes and allowing the conductive filler material to be left only on the wall surface of the through hole.

10. The method for manufacturing a circuit board of claim 9, wherein a hole diameter of the part of the through hole from which the conductive filler material drops off is larger than a hole diameter of the other through holes.

11. A method for manufacturing a circuit board, the method comprising:
preparing a prepreg sheet including the through hole for an interlayer connection filled with the conductive filler material, which is produced in the removing of the mold release film from the prepreg sheet of claim 8, and a recognition mark including the through hole filled with a conductive filler material, and the through hole that is not filled with a conductive filler material or the through hole with the conductive filler material left on the wall surface thereof;
preparing an inner layer substrate provided with a circuit pattern and a laminate recognition pattern and a metal foil;
detecting the through hole filled with the conductive filler material, and the through hole that is not filled with a conductive filler material or the through hole with the conductive filler material left on the wall surface of the through hole in the recognition marks in the prepreg sheet and a laminate recognition pattern on the inner layer substrate, positioning them each other, and disposing the prepreg sheet on the inner layer substrate;
substantially positioning and disposing the metal foil on the prepreg sheet and then pressing and pressurizing by hot pressing; and
forming a through hole for exposure by detecting the through hole filled with the conductive filler material in the recognition marks.

12. The method for manufacturing a circuit board of claim 11, wherein the recognition mark in the prepreg sheet and the laminate recognition pattern on the inner layer substrate are detected and positioned through detection by a camera and image processing.

13. The method for manufacturing a circuit board of claim 11, wherein the forming of the through hole for exposure by detecting the through hole filled with a conductive filler material in the recognition marks includes detecting the through hole by an X-ray and drill-processing a center of gravity of the through hole.

14. A method for manufacturing a circuit board, the method comprising:
preparing a prepreg sheet including the through hole for an interlayer connection filled with the conductive filler material, which is produced in the removing of the mold release film from the prepreg sheet of claim 9, and a recognition mark including the through hole filled with a conductive filler material, and the through hole that is not filled with a conductive filler material or the through hole with the conductive filler material left on the wall surface thereof;
preparing an inner layer substrate provided with a circuit pattern and a laminate recognition pattern and a metal foil;
detecting the through hole filled with the conductive filler material, and the through hole that is not filled with a conductive filler material or the through hole with the conductive filler material left on the wall surface of the through hole in the recognition marks in the prepreg sheet and a laminate recognition pattern on the inner layer substrate, positioning them each other, and disposing the prepreg sheet on the inner layer substrate;
substantially positioning and disposing the metal foil on the prepreg sheet and then pressing and pressurizing by hot pressing; and
forming a through hole for exposure by detecting the through hole filled with the conductive filler material in the recognition marks.
